(19) United States
(12) Patent Application Publication
(10) Pub. No.: US 2017/0183770 A1
(43) Pub. Date: Jun. 29, 2017

(54) SUBSTRATE PROCESSING APPARATUS

(71) Applicant: HITACHI KOKUSAI ELECTRIC INC., Tokyo (JP)

(72) Inventors: Yasuaki KOMAE, Toyama-shi (JP); Takashi NOGAMI, Toyama-shi (JP); Hidenari YOSHIDA, Toyama-shi (JP); Tomoshi TANIYAMA, Toyama-shi (JP); Shigeru ODAKE, Toyama-shi (JP)

(73) Assignee: HITACHI KOKUSAI ELECTRIC INC., Tokyo (JP)

(21) Appl. No.: 15/459,772

(22) Filed: Mar. 15, 2017

Related U.S. Application Data
(63) Continuation of application No. PCT/JP2015/076285, filed on Sep. 16, 2015.

(30) Foreign Application Priority Data
Sep. 30, 2014 (JP) 2014-200883

(51) Int. Cl. C23C 16/44; C23C 16/52; C23C 16/455

(52) U.S. Cl. CPC C23C 16/4412; C23C 16/455; C23C 16/52; H01L 21/02164

(57) ABSTRACT

There is provided a substrate processing apparatus including a first exhaust system which is connected to a first pump and a second pump of a type different from the first pump and is configured to exhaust the interior of a process chamber, a second exhaust system which is connected to the second pump and is configured to exhaust the interior of the process chamber and a control part configured to control the first exhaust system and the second exhaust system such that, when the processing gas is exhausted from the interior of the process chamber, the interior of the process chamber is first exhausted by the second exhaust system, and then an exhaust path is switched from the second exhaust system to the first exhaust system after an internal pressure of the process chamber reaches a predetermined pressure, to exhaust the process chamber by the first exhaust system.

### CROSS-REFERENCE TO RELATED APPLICATION(S)

This application is a bypass continuation application of international application No. PCT/JP2015/076285 having an international filing date of Sep. 16, 2015 and designating the United States, the international application being based upon and claiming the benefit of priority from Japanese Patent Application No. 2014-200883, filed on Sep. 30, 2014, the entire contents of which are incorporated herein by reference.

### TECHNICAL FIELD

The present disclosure relates to a substrate processing apparatus,

### BACKGROUND

With the miniaturization of semiconductor devices and the increase in wafer diameter, there is a tendency to increase the volume inside a process chamber. As the volume inside the process chamber increases, it takes a longer time to exhaust a residual gas from the process chamber than before. This has the effect that the time required for film formation is longer than that of a conventional process.

There has been conventionally proposed a technique in which three types of pumps having different exhaust characteristics are simultaneously driven to exhaust the interior of the process chamber.

If the exhaust of the interior of the process chamber is inefficiently performed, it takes time to complete the exhaust, which may have an adverse effect on the productivity.

### SUMMARY

The present disclosure provides some embodiments of a technique capable of exhausting the interior of a process chamber with high efficiency.

According to one embodiment of the present disclosure, there is provided a substrate processing apparatus including: a process chamber configured to process a substrate; a processing gas supply system configured to supply a processing gas into the process chamber; a first exhaust system which is connected to a first pump and a second pump of a type different from the first pump and is configured to exhaust the interior of the process chamber; a second exhaust system which is connected to the second pump and is configured to exhaust the interior of the process chamber; and a control part configured to control the first exhaust system and the second exhaust system such that, when the processing gas is exhausted from the interior of the process chamber, the interior of the process chamber is first exhausted by the second exhaust system, and then an exhaust path is switched from the second exhaust system to the first exhaust system after the internal pressure of the process chamber reaches a predetermined pressure, to exhaust the interior of the process chamber by the first exhaust system.

### BRIEF DESCRIPTION OF THE DRAWINGS

FIG. 1 is an oblique perspective view of a substrate processing apparatus according to an embodiment of the present disclosure.

FIG. 2 is a vertical sectional view of a processing furnace according to an embodiment of the present disclosure.

FIG. 3 is a horizontal sectional view of the processing furnace according to the embodiment of the present disclosure.

FIG. 4 is a schematic diagram of a gas exhaust system according to an embodiment of the present disclosure.

FIG. 5A is a diagram showing a change in internal pressure of a process chamber according to a conventional example and FIG. 5B is a diagram showing a change in internal pressure of a process chamber according to an embodiment of the present disclosure.

FIG. 6 is a schematic configuration diagram of a controller of the substrate processing apparatus suitably used in an embodiment of the present disclosure, in which a control system of the controller is shown in a block diagram.

### DETAILED DESCRIPTION

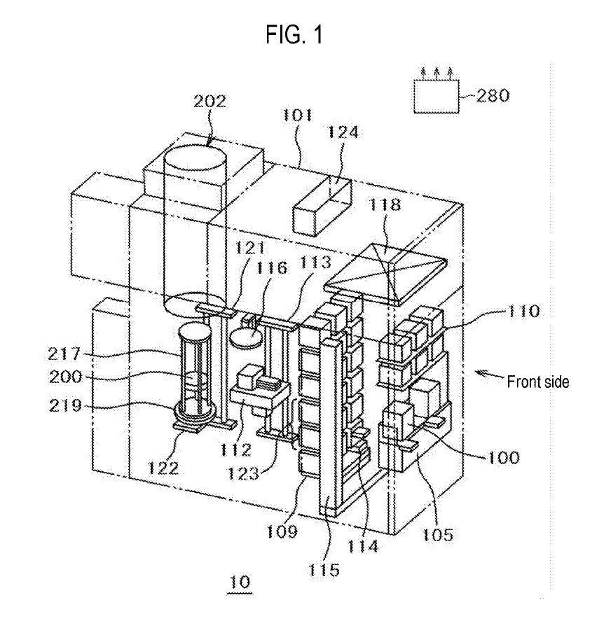

A configuration example of a substrate processing apparatus that performs a substrate processing process as one process of manufacturing a semiconductor device (IC) in a mode for carrying out the present disclosure will be described with reference to FIG. 1.

As shown in FIG. 1, a substrate processing apparatus 10 according to an embodiment of the present disclosure includes a housing 101. A pod 110 is used as a wafer carrier (substrate container) in order to transfer a wafer 200, which is a substrate made of silicon or the like, into and out of the housing 101.

An I/O stage (pod delivery table) 105 is installed in the front side of the housing 101. The pod 110 is carried in and loaded on the I/O stage 105 by an in-process transfer device (not shown) outside housing 101 and is unloaded from the I/O stage 105 outside of the housing 101.

A pod shelf (substrate container mounting shelf) 114 is installed at a substantially central portion in the front-rear direction in the housing 101. The pod shelf 114 is configured to store a plurality of pods 110 in a plurality of stages and a plurality of columns. A transfer shelf 123 is installed as a part of the pod shelf 114 and a pod 110 to be transferred by a wafer transfer mechanism 112, which will be described later, is stored in the transfer shelf 123. The transfer shelf 123 is provided with a pod opener (not shown) for opening and closing the lid of the pod.

A pod transfer device (substrate container transfer device) 115 is interposed between the I/O stage 105 and the pod shelf 114. The pod transfer device 115 can transfer the pod 110 between the I/O stage 105, the pod shelf 114 and the transfer shelf 123.

The wafer transfer mechanism (substrate transfer mechanism) 112 is installed in the rear side of the transfer shelf 123. The wafer transfer mechanism 112 includes a tweezer (a holder for substrate transfer) which holds the wafer 200 in a horizontal posture. The wafer transfer mechanism 112 can pick up the wafer 200 from the inside of the pod 110 on the transfer shelf 123, charge the wafer 200 on a boat (substrate holder) 217 to be described later or discharge the wafer 200 from the boat 217, and store the wafer 200 in the pod 110 on the transfer shelf 123.

A processing furnace 202 is installed above the rear side of the housing 101. The lower end portion of the processing furnace 202 is configured to be opened and closed by a furnace opening shutter (furnace opening/closing mechanism) 116. The configuration of the processing furnace 202 will be described later.

A boat elevator (substrate holder elevating mechanism) 121 as a driving mechanism configured to transfer the boat 217 in/out of the processing furnace 202 by lifting up/down the boat 217 is installed below the processing furnace 202. An arm 122 as a lifting platform is installed in the boat elevator 121. A seal cap 219 is installed in a horizontal posture on the arm 122. The seal cap 219 vertically supports the boat 217 and functions as a lid which air-tightly closes the lower end portion of the processing furnace 202 when the boat 217 is lifted up by the boat elevator 121.

The boat 217 has a plurality of wafer holding members (supports) and is configured to hold a plurality of wafers 200 (e.g., about 25 to 200 wafers) in a horizontal posture, with their centers aligned and with them vertically arranged in multiple stages. The detailed configuration of the boat 217 will be described later.

Next, an outline of an operation of the substrate processing apparatus 10 according to the embodiment of the present disclosure will be described with reference to FIG. 1. The substrate processing apparatus 10 is controlled by a controller 280 to be described later. First, a pod 110 is loaded on the I/O stage 105 by the in-process transfer device (not shown). The pod 110 on the I/O stage 105 is transferred to a designated position of the pod shelf 114 by the pod transfer device 115. The pod 110 is temporarily stored at the designated position of the pod shelf 114 and then is transferred again from the pod shelf 114 to the transfer shelf 123 by the pod transfer device 115. Alternatively, the pod 110 may be directly transferred from the I/O stage 105 to the transfer shelf 123.

When the pod 110 is transferred to the transfer shelf 123, the lid of the pod 110 is opened by the pod opener. The wafer 200 in the pod 110 is picked up from a wafer entrance of the pod 110 by the wafer transfer mechanism 112 and is charged in the boat 217.

When the prescribed number of wafers 200 is charged in the boat 217, the furnace opening shutter 116 which has closed the lower end portion of the processing furnace 202 is opened, so that an opening of the lower end portion of the processing furnace 202 is opened. Subsequently, as the seal cap 219 on which the boat 217 loaded is raised by the boat elevator 121, the boat 217 holding a group of wafers 200 to be processed is loaded into the processing furnace 202 (boat loading). After the boat loading, the opening of the lower end portion of the processing furnace 202 is closed by the seal cap 219, the interior of the processing furnace 202 is depressurized to a predetermined pressure, and optional processing is performed on the wafers 200, as will be described later.

After the processing, the wafer 200 and the pod 110 are discharged from the housing 101 in the procedure reverse to the above-described procedure.

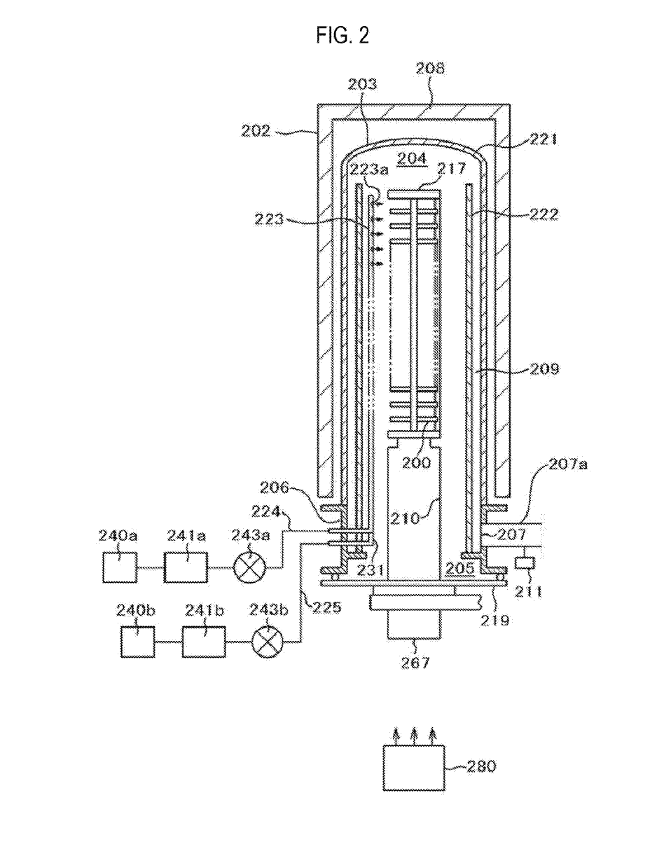

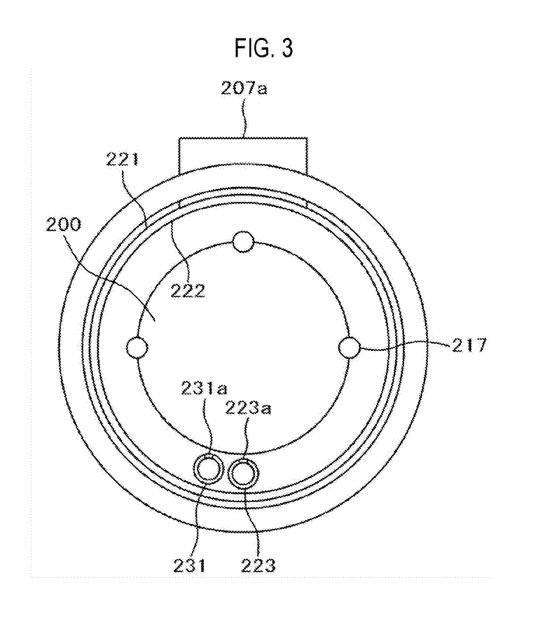

Next, the configuration of the processing furnace 202 according to the present embodiment will be described with reference to FIGS. 2 and 3.

The processing furnace 202 has an outer tube 221 as a vertical outer reaction tube inside the processing furnace 202. The outer tube 221 has a substantially cylindrical shape with its upper end closed and its lower end opened. The outer tube 221 is arranged in the vertical direction such that the opened lower end faces downward and the center line of the axial direction of the outer tube 221 becomes vertical, and is fixedly supported by the housing 101. An inner tube 222 as an inner reaction tube is installed inside the outer tube 221. In this example, both the inner tube 222 and the outer tube 221 are made of a material having high heat resistance such as quartz (SiO₂) or silicon carbide (SiC) and are integrally molded in a substantially cylindrical shape. A process tube 203 as a reaction tube is constituted by the inner tube 222 and the outer tube 221.

The inner tribe 222 is formed in a substantially cylindrical shape with its upper end closed and its lower end opened. A process chamber 204 for accommodating and processing a plurality of wafers 200 held in a horizontal posture and in multiple stages by the boat 217 as the substrate holder is formed inside the inner tube 222. A lower end opening of the inner tube 222 constitutes a furnace opening 205 for taking in/out the boat 217 holding the group of wafers 200. Therefore, the inner diameter of the inner tube 222 is set to be larger than the maximum outer diameter of the boat 217 holding the group of wafers 200.

The inner diameter of the outer tube 221 is set to be larger than the outer diameter of the inner tube 222. The outer tube 221 is formed in a substantially cylindrical shape with its upper end closed and its lower end opened and is installed concentrically with the inner tube 222 so as tc surround the outer side of the inner tube 222.

The lower ends of the inner tube 222 and the outer tube 221 are air-tightly sealed by a manifold 206 whose horizontal section has a substantially circular ring shape. The inner tube 222 and the outer tube 221 are removably attached to the manifold 206 for maintenance/inspection work and cleaning operation. As the manifold 206 is supported by the housing 101, the process tube 203 is installed vertically to the housing 101.

An exhaust pipe 207a for exhausting the internal atmosphere of the process chamber 204 is connected to a portion of the side wall of the manifold 206. An exhaust port 207 for exhausting the internal atmosphere of the process chamber 204 is formed in a connection portion of the manifold and the exhaust pip 207a. The exhaust pipe 207a communicates to an exhaust path 209 constituted by a gap formed between the inner tube 222 and the outer be 221 the exhaust port 207. The horizontally sectional shape of the exhaust path 209 has a substantially circular ring shape having a constant width. The exhaust pipe 207a and the exhaust port 207 constitute a part of an exhaust system to be described later.

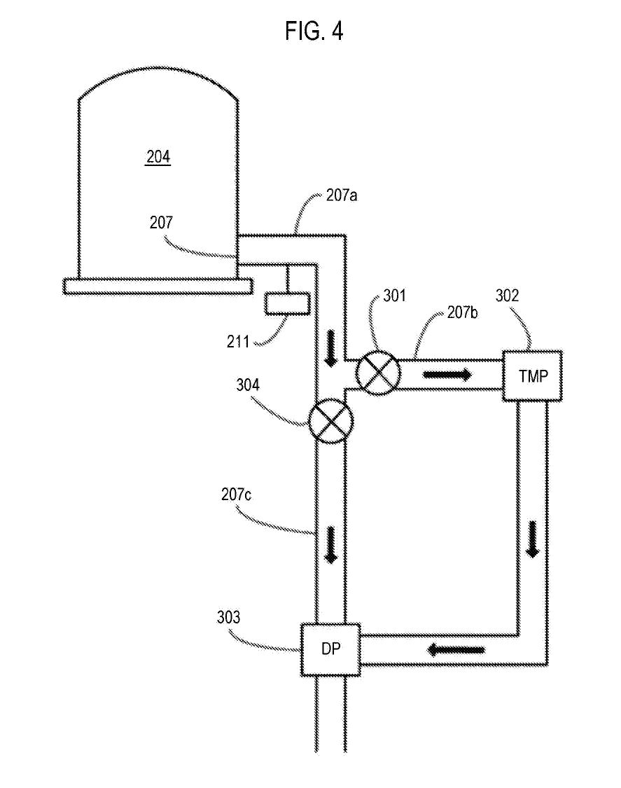

Next, the configuration of the exhaust system will be described with reference to FIG. 4.

As shown in FIG. 4 a first exhaust pipe 207b and a second exhaust pipe 207c are connected to the exhaust pipe 207a. That is, the exhaust pipe 207a is installed so as to branch into the first exhaust pipe 207b and the second exhaust pipe 207c. The first exhaust pipe 207b and the second exhaust pipe 207c join at the downstream side thereof, so that it may be said that those are integrated.

A pressure sensor 211 for detecting the internal pressure of the process chamber 204 is installed at an upstream portion of the exhaust pipe 201a. A gate valve 301 as a first exhaust valve and a turbo molecular pump (TMP) 302, which is an axial flow pump, as a first pump, are installed in the first exhaust pipe 207b in order from the upstream side. The TMP 302 is installed at a position away from the process chamber 204 by a predetermined distance (flow path distance or pipe length). An APC valve 304 as a second exhaust valve and a dry pump (DP) 303 as a second pump are installed in the second exhaust pipe 207c in order from the upstrean side. The DP 303 as th second pump may be a pump of a different type from the TMP 302 as the first pump. Although FIG. 4 shows an example its which the DP 303 is installed at a joining portion of the first exhaust pipe 207b and the second exhaust pipe 207c, the DP 303 may be installed in the downstream side of the joining portion (connection portion) of the first exhaust pipe 207b and the second exhaust pipe 207c. In any case, with this configuration, when exhausting the internal atmosphere of the process chamber 204 through the first exhaust pipe 207b, the exhaust is carried out using both the TMP 302 and the DP 303. When exhausting the internal atmosphere of the process chamber 204 through the second exhaust pipe 207c, the exhaust is carried out using the DP 303 alone without using the TMP 302.

A first exhaust system is mainly constituted by the first exhaust pipe 207b and the gate valve 301. The exhaust pipe 207a and the pressure sensor 211 may be included in the first exhaust system. The first exhaust system is connected to the TMP 302 and the DP 303. A second exhaust system is mainly constituted by the second exhaust pipe 207c and the APC valve 304. The exhaust pipe 207a and the pressure sensor 211 may be included in the second exhaust system. The second exhaust system is connected to the DP 303. An exhaust system is mainly constituted by the first exhaust system and the second exhaust system. When the term “exhaust system” is used herein, it may include only the first exhaust system, only the second exhaust system, or both.

The TMP 302 and the DP 303 are electrically connected to a controller 280. The controller 280 is configured to control the TMP 302 and the DP 303 so that the TMP 302 and the DP 303 are driven or stopped at a desired timing.

A distance between the process tube 203 (the process chamber 204) and the TMP 302 may be desirably within 1 m. When the distance between the process tube 203 and the TMP 302 exceeds 1 m, since the pipe volume and pipe surface area of the exhaust path (including the exhaust pipe 207a and the first exhaust pipe 207b) from the process tube 203 to the TMP 302 increase, the exhaust of the interior of the process chamber 204 and the exhaust path becomes burdensome, so that the exhaust performance of the TMP 302 cannot be fully utilized. Considering an installation space of the gate valve 301 and an exhaust pipe length of the first exhaust system, the optimal dimension is that the distance between the process tube 203 and the TMP 302 is within 1 m. When the TMP 302 is installed within this distance of 1 m, the TMP 302 can be effectively driven. In order to arrange the TMP 302 at a position relatively close to the process tube 203, the TMP 302 may be installed between the process tube 203 and the housing 101, that is, inside the substrate processing apparatus 10. Further, the TMP 302 is installed at a position closer to the process tube 203 than the DP 303. That is, the length of the exhaust path from the process tube 203 is shorter to the TMP 302 than to the DP 303.

The seal cap 219 for closing the lower end opening of the manifold 206 is configured to be in contact with the manifold 206 from the lower side in the vertical direction. The seal cap 219 is formed in a disc shape having an outer diameter equal to or larger than the outer diameter of the outer tube 221 and is configured to be vertically moved, with the disc shape kept in the horizontal posture, by the boat elevator 121 installed vertically outside the outer tube 221.

The boat 217 as the substrate holder for holding the wafer 200 is vertically supported above the seal cap 219. The boat 217 has a pair of end plates at the top and bottom and a plurality of wafer holding members, three wafer holding members in this example (boat supports) vertically installed to extend between both of the end plates. The end plates and the wafer holding members are made of a material having high heat resistance such as quartz (SiO₂) or silicon carbide (SiC).

In each of the wafer holding members, a plurality of sets of holding grooves engraved in the horizontal direction are formed at equal intervals in the longitudinal direction. Each wafer holding member is installed in such a manner that the holding grooves are opposed to each other and the vertical positions (positions in the vertical direction) of the holding grooves of each wafer holding member are aligned with each other. As the peripheral edges of the wafers 200 are respectively inserted into the holding grooves of the same stage in the plurality of wafer holding members, the plurality of wafers 200 are held in a horizontal posture in multiple stages with the centers of the wafers aligned with each other.

In addition, a boat mounting 210 is installed between the boat 217 and the seal cap 219. The boat mounting 210 is made of a heat resistant material such as quartz (SiO₂) or silicon carbide (SiC). The boat mounting 210 is provided to prevent heat from a heater 208, which will be described later, from being transferred to a side of the manifold 206.

A boat rotation mechanism 267 for rotating the boat 217 is installed in the lower side of the seal cap 219 (the opposite side to the process chamber 204). A boat rotation shaft of the boat rotation mechanism 267 penetrates through the seal cap 219 and supports the boat 217 from a lower side. By rotating the boat rotation shaft, it is possible to rotate the wafers 200 in the process chamber 204.

The seal cap 219 is configured to be vertically moved by the above-mentioned boat elevator 121 so that the boat 217 can he transferred into and out of the process chamber 204.

The boat rotation mechanism 267 and the boat elevator 121 are electrically connected to the controller 280. The controller 280 is configured to control the boat rotation mechanism 267 and the boat elevator 121 to perform a desired operation at a desired timing.

The heater 208 as a heating mechanism for heating the interior of the process tube uniformly in entirety or to a predetermined temperature distribution is installed outside the outer tube 221 so as to surround the outer tube 221. The heater 208 can be vertically installed by being supported by the housing 101 of the substrate processing apparatus 10 and is constituted by a resistance heater such as a carbon heater.

A temperature sensor 290 (not shown) as a temperature detector is installed inside the inner tube 222. The heater 208 and the temperature sensor 290 are electrically connected to the controller 280.

The controller 280 is configured to control the supply amount of current to the heater 208 based on temperature information detected by the temperature sensor 290 so that the temperature of the interior of the process chamber 204 becomes a desired temperature distribution at a desired timing.

A processing gas supply system will be described with reference to FIG. 2. As shown in FIG. 2, a precursor gas supply nozzle 223 for supplying a precursor gas, which is a processing gas, into the process chamber 204 penetrates through the side wall of the manifold 206 and is installed to extend along the inner wall of the inner tube 222 (that is, the inner wall of the process chamber 204) vertically in the stack direction of the wafers 200. Although one precursor gas supply nozzle is used in the example of FIG. 2, a plurality of precursor gas supply nozzles may be used.

In addition, a reaction gas supply nozzle 231 (see FIG. 3) for supplying a reaction gas as a processing gas into the process chamber 204 penetrates through the side wall of the manifold 206 and is installed to extend along the inner wall of the inner tube 222 (that is, the inner wall of the process chamber 204) vertically in the stack direction of the wafers 200 in the same manner as the precursor gas supply nozzle 223.

As shown in FIG. 2, a precursor gas supply pipe 224 as a precursor gas supply line is connected to the precursor gas supply nozzle 223. A precursor gas supply source 240a for supplying a precursor gas such as dichlorosilane (SiH₂Cl₂, abbreviation: DCS) gas, a mass flow controller (MFC) 241a as a flow rate control device, and an opening/closing valve 243a are installed in the precursor gas supply pipe 224 in order from the upstream side.

In addition, a reaction gas supply pipe 225 as a reaction gas supply line is connected to the reaction gas supply nozzle 231. A reaction gas supply source 240b for supplying a reaction gas such as an oxygen (O₂) gas, an MFC 241b and an opening/closing valve 243b are installed in the reaction gas supply pipe 225 in order from the upstream side.

The MFCs 241a and 241b and the opening/closing valves 243a and 243b are electrically connected to the controller 280. The controller 280 is configured to control the MFCs 241a and 241b and the opening/closing valves 243a and 243b so that the type of gas to be supplied into the process chamber 204 becomes a desired type of gas at a desired timing or the flow rate of the supplied gas becomes a desired flow rate at a desired timing.

As shown in FIGS. 2 and 3, a plurality of discharge holes 223a and 231a is installed in cylindrical portions of the precursor gas supply nozzle 223 and the reaction gas supply nozzle 231 within the process chamber 204 so as to be arranged in the vertical direction. The number of discharge holes 223a and 231a is set to be equal to the number of wafers 200 held in the boat 217, for example. The height positions of the discharge holes 223a and 231a are set so as to face a space between adjacent wafers 200 vertically held by the boat 217, for example. The diameters of the discharge holes 223a and 231a may be set to different sizes in the vertical direction so that the supply amount of gas to each wafer 200 becomes uniform.

The gases supplied from the precursor gas supply nozzle 223 and the reaction gas supply nozzle 231 into the process chamber 204 flow from the upper open end of the inner tube 222 into the exhaust path 209, then flow into the exhaust pipe 207a via the exhaust port 207, and are discharged out of the processing furnace 202.

A precursor gas supply system is mainly constituted by the precursor gas supply pipe 224, the MFC 241a and the opening/closing valve 243a. The precursor gas supply source 240a and the precursor gas supply nozzle 223 may be included in the precursor gas supply system. A reaction gas supply system is mainly constituted by the reaction gas supply pipe 225, the MFC 241b and the opening/closing valve 243b. The reaction gas supply source 240b and the reaction gas supply nozzle 231 may be included in the reaction gas supply system. A processing gas supply system is constituted by the precursor gas supply system and the reaction gas supply system. When a precursor gas is referred to as a first processing gas, the precursor gas supply system may be referred to as a first processing gas supply system. When a reaction gas is referred to as a second processing gas, the reaction gas supply system may be referred to as a second processing gas supply system. When the term “processing gas” is used herein, it may include only the first processing gas, only the second processing gas, or both.

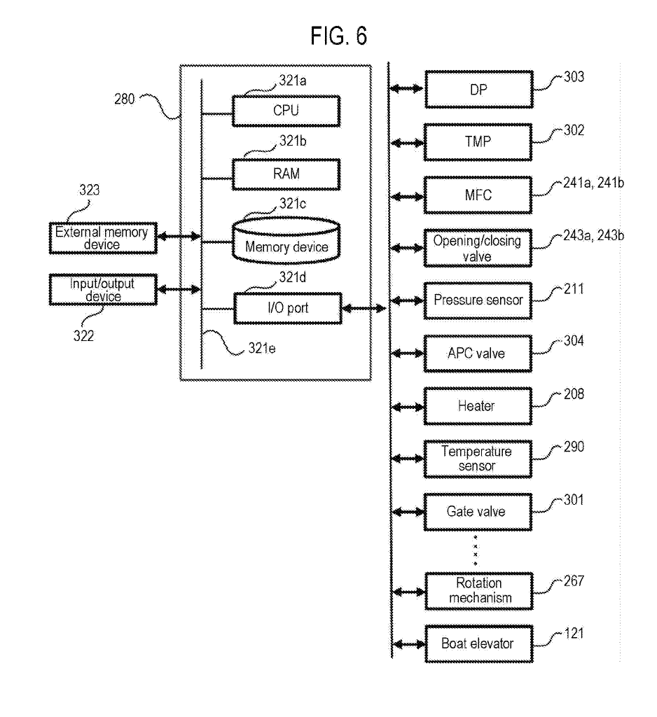

As shown in FIG. 6, a controller 280, which is a control part (control means), may be configured as a computer including a central processing unit (CPU) 321a, a random access memory (RAM) 321b, a memory device 321c and an I/O port 321d. The RAM 321b, the memory device 321c and the I/O port 321d are configured to exchange data with the CPU 321a via an internal bus 321e. An input/output device 322 formed of, e.g., a touch panel or the like, is connected to the controller 280.

The memory device 321c is configured with, e.g., a flash memory, a hard disc drive (HDD) or the like. A control program for controlling operations of a substrate processing apparatus and a process recipe, in which sequences and conditions of a film forming process to be described later are written, are readably stored in the memory device 121c. The process recipe is a combination for causing the controller 280 to execute each sequence in the film forming process, which will be described later, to obtain a predetermined result and functions as a program. Hereinafter, the process recipe and the control program will be collectively referred to as a “program”. When the term “program” is used herein, it may indicate a case of including only the recipe, a case of including only the control program, or a case of including both the recipe and the control program. The RAM 321b is configured as a memory area (work area) in which a program or data read by the CPU 321a is temporarily maintained.

The I/O port 321d is connected to the MFCs 241a and 241b, the opening/closing valves 243a and 243b, the gate valve 301, the pressure sensor 211, the APC valve 304, the heater 208, the temperature sensor 290 (not shown), the rotation mechanism 267, the boat elevator 121 and so on.

The CPU 321a is configured to read and execute the control program from the memory device 321c. The CPU 321a also reads the recipe from the memory device 321c according to an input of an operation command from the input/output device 322. The CPU 321a is configured to control the flow rate adjusting operations of various kinds of gases by the MFCs 241a and 241b, the opening/closing operations of the opening/closing valves 243a and 243b, the opening/closing operation of the gate valve 301, the pressure regulating operation performed by the APC valve 304 based on the pressure sensor 211, the driving and stopping of the TMP 302 and the DP 303, the temperature adjusting operation performed by the heater 208 based on the temperature sensor 290, the operations of rotating the boat 217 and adjusting the rotation speed of the boat 217 with the rotation mechanism 267, the operation of moving the boat 217 up and down with the boat elevator 121, and so on, according to contents of the read recipe.

The controller 280 may not be limited to a case configured by a general-purpose computer, but the controller 280 may be configured by a dedicated computer. For example, the controller 280 of this embodiment may be configured by installing, on the general-purpose computer, the aforementioned program stored in an external memory device 323 (for example, a magnetic tape, a magnetic disk such as a flexible disk or a hard disk an optical disk such as a CD or DVD, a magneto-optical disk such as an MO, a semiconductor memory such as a USB memory or a memory card). However, the program may be supplied to the computer using communication means such as the Internet or a dedicated line, instead of using the external memory device 323. The memory device 321e or the external memory device 323 is configured as a computer-readable recording medium. Hereinafter, the memory device 321c and the external memory device 323 will be collectively referred to as a “recording medium.” When the term “recording medium” is used herein, it may indicate a case of including only the memory device 321c, a case of including only the external memory device 323, or a case of including both the memory device 321c and the external memory device 323.

Next, a substrate processing method according to an embodiment of the present disclosure will be described with respect to a film forming process in an IC manufacturing method as an example. First, in a wafer charging step, wafers 200 are charged in the boat 217. Specifically, a plurality of parts on the circumferential edges of the wafers 200 is inserted so as to set on holding grooves of a plurality of wafer holding members, peripheral portions of the plurality of parts of the wafers 200 set on the respective holding grooves, and the wafers 200 are charged and held in the boat 217 so as to support the weight of the wafers 200. In the charged state of the boat 217, the plurality of wafers 200 is horizontally aligned and held in parallel with each other in multiple stages with their centers aligned.

Next, in a boat loading step, the boat 217 holding the plurality of wafers 200 is loaded into the process chamber 204 under an atmospheric pressure state (boat loading). Specifically, the boat 217 charged with the wafers 200 is moved up in the vertical direction by the boat elevator 121 to be loaded into the process chamber 204 in the inner tube 222, and is placed in the process chamber 204 as shown in FIG. 2.

Next, in a film forming step, while the boat 217 is being rotated, a processing gas (a precursor gas or a reaction gas) is introduced into the process chamber 204. That is, when the valve 243a is opened, a predetermined precursor gas is supplied into the precursor gas supply nozzle 223 and is introduced from the plurality of discharge holes 223a into the process chamber 204 in the inner tube 222. In addition, when the valve 243h is opened, a predetermined reaction gas is supplied into the reaction gas supply nozzle 231 and is introduced from the plurality of discharge holes 231a into the process chamber 204 in the inner tube 222.

For example, in a case of forming a silicon oxide film (SiO₂ film, hereinafter also simply, referred to as a SiO film) on each wafer 200, a DCS gas as the precursor gas and an O₂ gas as the reaction gas are alternately supplied to the wafer 200 in the process chamber 204. That is, a step of supplying the DCS gas as the precursor gas to the wafer 200 in the process chamber 204 and a step of supplying the O₂ gas as the reaction gas to the wafer 200 in the process chamber 204 are alternately performed a predetermined number of times with a step of exhausting a gas in the process chamber 204 interposed therebetween. More specifically, one cycle including a precursor gas (DCS gas) supplying step → a precursor gas exhausting step → a reaction gas (O₂ gas) supplying step → an reaction gas exhausting step is performed a predetermined number of times. In the precursor gas exhausting step and the reaction gas exhausting step, an inert gas such as a N₂ gas may be supplied into the process chamber 204. Hereinafter, the precursor gas exhausting step and the reaction gas exhausting step may be collectively referred to as an exhausting step. When the term “exhausting step” is used herein, it may include only the precursor gas exhausting step, only the reaction gas exhausting, or both.

The processing Conditions at this tittle are exemplified as follows.

Temperature of wafer 200: 250 to 700 degrees C

Internal pressure of process chamber: 1 to 4,000 Pa

DCS gas supply flow rate: 1 to 2,000 sccm

O₂ gas supply flow rate: 100 to 10,000 sccm

N₂ gas supply flow rate: 100 to 10,000 sccm

By processing the wafer 200 under the abovementioned processing procedures and processing conditions, a SiO₂film having a predetermined film thickness is formed on the wafer 200.

Hereinafter, the operation in the exhausting step will be described. The exhausting step includes a first exhausting step and a second exhausting step, to be described below.

### First Exhausting Step

At the start of exhaust of a gas in the process chamber 204, the gate valve 301 is closed, the APC valve 304 is opened, and the DP 303 as the second pump is driven to start vacuum-exhaust in the process chamber 204 from the second exhaust system. The exhaust by the DP 303 is continued until the internal pressure of the process chamber 204 reaches a predetermined (about 100 to 10 Pa) pressure value (near vacuum state), that is, it becomes close to a high vacuum region. The internal pressure of the process chamber is measured by the pressure sensor 211.

### Second Exhausting Step

When the internal pressure of the process chamber 204 reaches the predetermined pressure value, the TMP 302 is driven, the gate valve 301 is opened and the APC valve 304 is simultaneously closed, so that an exhaust path is switched from the second exhaust system to the first exhaust system and the interior of the process chamber 204 is exhausted from the first exhaust system. At this time, the DP 303 is kept driven. Alternatively, the TMP 302 may be driven before the internal pressure of the process chamber 204 reaches the predetermined pressure value.

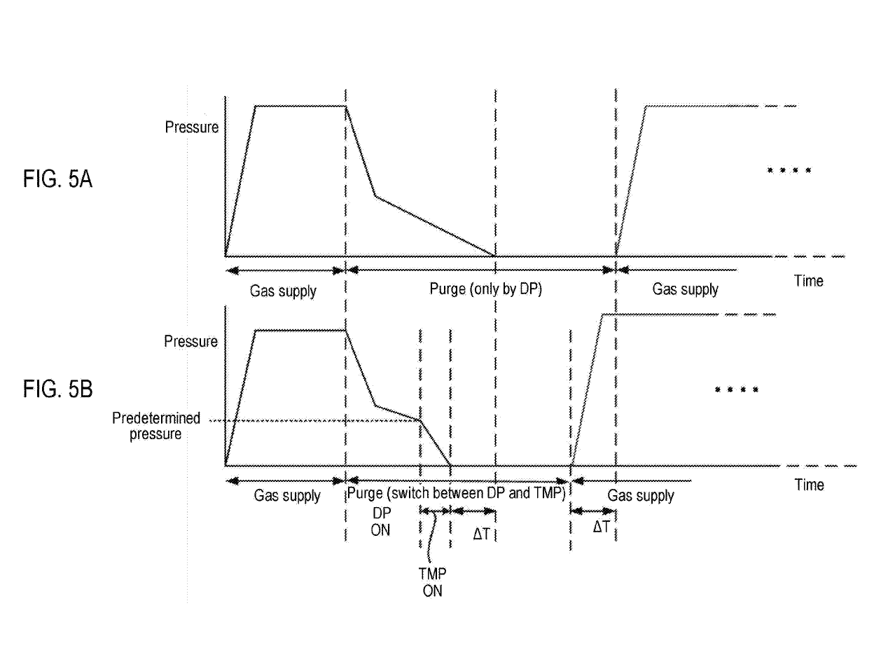

With reference to FIGS. 5A and 5B, a case of exhausting the interior of the process chamber 204 in a single exhaust path using only the DP 303 (a conventional example) and a case of exhausting the interior of the process chamber 204 by switching the exhaust path when the internal pressure of the process chamber reaches a predetermined pressure using both the DP 303 and the TMP 302 (an embodiment of the present disclosure) will be compared.

FIG. 5A shows a change in pressure within the process chamber 204 according to the conventional example. The first processing gas is supplied into the process chamber and then the exhaust is started. At this time, the exhaust is performed only with the DP 303. As shown in FIG. 5A, as the pressure becomes lower, that is, as the interior of the process chamber 204 is exhausted, an exhaust speed of the DP 303 becomes lower and the exhaust efficiency decreases. In particular, a pressure gradient becomes smooth from a certain pressure value, wherein this pressure value is, about 1,000 Pa.

FIG. 5B shows a change in pressure within the process chamber 204 according to the embodiment of the present disclosure. The supply time of the first processing gas is the same as in FIG. 5A. First, the DP 303 is used to start the exhaust of the interior of the process chamber 204. The internal pressure of the process chamber 204 becomes lower, and the exhaust efficiency decreases from a certain pressure value like FIG. 5A, so that the pressure gradient becomes smooth. When the exhaust is performed up to a predetermined pressure (for example, about 100 to 10 Pa), the exhaust path is switched from the second exhaust system to the first exhaust system to perform the exhaust. That is, after the interior of the process chamber 204 is exhausted to the predetermined pressure by the DP 303, the interior of the process chamber 204 is exhausted by using the TMP 302.

When the internal pressure of the process chamber is about 100 Pa, the exhaust speed of the DP is about 10,000 L/min, while the exhaust speed of the TMP is about 120 L/min. When the internal pressure of the process chamber is about 1 Pa, the exhaust speed of the DP is about 2,000 L/min, while the exhaust speed of the TMP is about 60,000 L/min. In this way, since the TMP is superior to the DP in terms of exhaust efficiency in a low pressure region, the exhaust time of the case of FIG. 5B can be shortened by ΔT to be faster than that of the case of FIG. 5A. However, as compared with the case where the exhaust is performed only by the DP 303, the exhaust time can be shortened by ΔT indicated in FIG. 5A for one time purging.

In general, when byproducts or films adhere to a wing in the TMP, the TMP cannot be used because its performance is degraded or it breaks down, so that the TMP for conventional exhaust in a film forming process cannot be used. However, in the present disclosure, in the first exhausting step, a processing gas and byproducts remaining in the process chamber are removed up to an extent that they do not adversely affect the TMP. That is, by performing the exhaust to a predetermined pressure, it is possible to reduce the amount of the processing gas and byproducts remaining in the process chamber up to an extent that does not adversely affect the TMP. Thus, in the present disclosure, the TMP can be used in the exhaust in the film forming process.

The above-described exhausting step may he applied to both the precursor gas exhausting step and the reaction gas exhausting step or one of the precursor gas exhausting step and the reaction gas exhausting step.

According to the present embodiment, one or more effects set forth below may be achieved.

(1) By switching between the second exhaust system and the first exhaust system in accordance with the internal pressure of the process chamber, it is possible to efficiently exhaust the interior of the process chamber, so that the exhaust speed can be increased in all the pressure ranges, and an ultimate pressure (vacuum degree) can be sufficiently obtained.

(2) After reducing the amount of film forming gas or reaction byproduct remaining in the process chamber up to an extent that does not affect the TMP, since the TMP is driven to perform the exhaust, it is possible to use the TMP without breakdown during a film forming process.

(3) Since the exhaust time can be shortened by switching between the DP and the TMP in accordance with the internal pressure of the process chamber, it is possible to improve a throughput.

(4) Since the interior of the process chamber can be sufficiently exhausted, it is possible to increase the cleanliness in the process chamber.

Although the case of alternately supplying a precursor gas and a reaction gas in the film forming step has been described in the above embodiments, the present disclosure can be applied to a case of simultaneously supplying the precursor gas and the reaction gas. For example, the present disclosure can be also applied to a process including a step of supplying the precursor gas and the reaction gas into the process chamber and a step of exhausting the precursor gas and the reaction gas from the interior of the process chamber.

In addition, the example where the DCS gas is used as the precursor gas has been described in the above embodiments. However, as the precursor gas, in addition to the DCS gas, it may use, e.g., an inorganic precursor gas such as a monochlorosilane abbreviation: MCS) gas, a hexachlorodisilane (Si₂Cl₆, abbreviation: HCDS), tetrachlorosilane, i.e., silicon tetrachloride (SiCl₄, abbreviation: STC) gas, a trichlorosilane (SiHCl₃, abbreviation: TCS) gas, a tetrafluorosilane (SiF₄, abbreviation: TFS) gas, a hexafluorodisilane (Si₂F₆, abbreviation: HFDS) gas, a trisilane(Si₃H₈, abbreviation: TS) gas, a disilane (Si₂H₆, abbreviation: DS) gas, a monosilane (SiH₄, abbreviation: MS) gas or the like, an organic precursor gas such as a tetrakis(dimethylamino)silane (Si[N(CH₃)₂]₄, abbreviation: 4DMAS) gas, a trisdimethylaminosilane (Si[N(CH₃)₂]₃H, abbreviation: 3DMAS) gas, a bis(diethylamino) silane (Si[N(C₂H₅)₂]₂H₂, abbreviation: BDEAS) gas or a bis(tert-butylamino)silane (SiH₂[NH(C₄H₉)]₂, abbreviation: BTBAS) gas, or the like.

In addition, the example where the O₂ gas is used as the reaction gas has been described in the above embodiments. However, as the reaction gas, in addition to the O₂ gas, it may to use, e.g., an oxygen-containing gas (oxidizing gas) such as water vapor (H₂O gas), a nitrogen monoxide (NO) gas, a nitrous oxide (N₂O) gas, a nitrogen dioxide NO₂) gas, a carbon monoxide (CO) gas, a carbon dioxide (CO₂) gas, an ozone (O₃) gas, a mixture of H₂ gas and O₂ gas, a mixture of H₂ gas and O₃ gas or the like.

In addition, in a case of using a H₂O gas as the reaction gas or in a case of generating a H₂O gas in the course of forming a film, since it is hard to exhaust the H₂O gas, it takes time to exhaust the interior of the process chamber, which results in lengthening the time required to form a film. At least, when the above exhausting step is applied after a process of using the H₂O gas as the reaction gas or after a process of generating the H₂O gas, it is possible to significantly shorten the time required to exhaust, thereby making the effects of the present disclosure particularly remarkable.

In addition, the example where the silicon oxide film is formed has been described in the above embodiments. However, the present disclosure can also be applied to the general processes of forming CVD films such as a silicon nitride film (Si₃N₄ film, hereinafter also simply referred to as a SiN film), a silicon oxynitride film (SiON film), a silicon carbonitride (SiCN film), a silicon oxycarbonitride film (SiOCN film), a silicon oxycarbide film (SiOC film) and the like and further the general substrate processing processes including a depressurizing and exhausting step in a semiconductor device manufacturing process, such as an oxidizing step, a diffusing step or an annealing step.

The present disclosure is not limited to the above embodiments but it is to be understood that various modifications can be made without departing from the spirit and scope of the present disclosure.

While the case where the processing is performed on a wafer has been described in the above embodiments, the processing target may be a photo mask, a printed wiring board, a liquid crystal panel, a compact disc, a magnetic disk or the like.

In addition, the example in which films are formed using a batch-type substrate processing apparatus capable of processing a plurality of substrates at a time has been described in the above embodiments. However, the present disclosure is not limited to the above embodiments but may be appropriately applied to, e.g., a case where films are formed using a single-wafer-type substrate processing apparatus capable of processing a single substrate or several substrates at a time. In addition, the example in which films are formed using a substrate processing apparatus provided with a hot-wall-type processing furnace has been described in the above embodiments. However, the present disclosure is not limited to the above embodiments but may be appropriately applied to a case where films are formed using a substrate processing apparatus provided with a cold-wall-type processing furnace. Even in these cases, the processing procedures and processing conditions may be the same as those in the above embodiments.

### Industrial Applicability

According to the substrate processing apparatus of the present disclosure, it is possible to efficiently exhaust the interior of a process chamber and improve the productivity.

According to the present disclosure in some embodiments, it is possible to provide a technique capable of exhausting the interior of a process chamber with high efficiency.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus comprising:
a process chamber confituired to process a substrate;
a processing gas supply system configured to supply a processing gas into the process chamber;
a first exhaust system which is connected to a first pump and a second pump of a type different from the first pump and is configured to exhaust the interior of the process chamber;
a second exhaust system which is connected to the second pump and is configured to exhaust the interior of the process chamber; and
a control part configured to control the first exhaust system and the second exhaust system such that, when the processing gas is exhausted from the interior of the process chamber, the interior of the process chambet is first exhausted by the second exhaust system, and then an exhaust path is switched from the second exhaust system to the first exhaust system after an internal pressure of the process chamber reaches a predetermined pressure, to exhaust the interior of the process chamber by the first exhaust system.

2. The substrate processing apparatus of Claim 1, wherein the first pump has higher exhaust efficiency in a low pressure region than the second pump.

3. The substrate processing apparatus of Claim 2, wherein the first pump is an axial flow pump and the second pump is a dry pump.

4. The substrate processing apparatus of Claim 3, wherein the first pump is installed away from the process chamber at a predetermined distance.

5. The substrate processing apparatus of Claim 4, wherein the predetermined distance is equal to or less than 1 m.

6. The substrate processing apparatus of Claim 5, wherein the first pump is installed inside a housing of the substrate processing apparatus.

7. The substrate processing apparatus of Claim 1, wherein the first exhaust system includes a gate valve and the second exhaust system includes an APC valve.

8. The substrate processing apparatus of Claim 4, wherein the first pump is installed at a location closer to the process chamber than the second pump.

9. The substrate processing apparatus of Claim 1, wherein the predetermined pressure is 10 to 100 Pa.

10. The substrate processing apparatus of Claim 7, wherein the control part is configured to control the APC valve and the gate valve such that the APC valve is opened and the gate valve is closed when the processing gas is exhausted, and the APC valve is closed and the gate valve is opened when the internal pressure of the process chamber reaches the predetermined pressure.

11. The substrate processing apparatus of Claim 10, wherein the control part is configured to control the processing gas supply system, the first exhaust system and the second exhaust system such that a first processing gas and a second processing gas are sequentially supplied, as the processing gas, into the process chamber, the interior of the process chamber is first exhausted by the second exhaust system before the second processing gas is supplied, an exhaust path is switched from the second exhaust system to the first exhaust system after the internal pressure of the process chamber reaches a predetermined pressure, and the interior of the process chamber is exhausted by the first exhaust system.
